(19) United States
(12) Patent Application Publication
(10) Pub. No.: US 2017/0316937 A1
(43) Pub. Date: Nov. 2, 2017

(54) Low-Temperature Formation Of Thin-Film Structures

(71) Applicant: Technische Universiteit Delft, Delft (NL)

(72) Inventors: Ryoichi Ishihara, Delft (NL); Michiel Van Der Zwan, Delft (NL); Miki Trifunovic, Delft (NL)

(21) Appl. No.: 15/523,611

(22) PCT Filed: Oct. 30, 2015
(86) PCT No.: PCT/NL2015/050761

§ 371 Date: May 1, 2017

(30) Foreign Application Priority Data
Oct. 30, 2014 (NL) 1041025
Oct. 31, 2014 (NL) 2013715

(51) Int. Cl. H01L 21/02; H01L 29/66

(52) U.S. Cl. CPC H01L 21/02678; H01L 29/66757; H01L 21/02686; H01L 21/02628; H01L 21/02164; H01L 21/02422; H01L 21/02236; H01L 21/02211; H01L 21/02532

(57) ABSTRACT

Methods for low-temperature formation of one or more thin-film semiconductor structures on a substrate that include the steps of, forming a (poly)silane layer over a substrate, transforming one or more parts of the (poly)silane layer in one or more thin-film solid-state semiconductor structures, by exposing the one or more parts with light from an

### FIELD OF THE INVENTION

The invention relates to low-temperature formation of thin-film structures, and, in particular, though not exclusively, to low-temperature methods for forming semiconductor and/or semiconductor oxide thin-film structures on the basis of polysilanes and thus film structures produced by such methods.

### BACKGROUND OF THE INVENTION

A promising technique for producing flexible electronics is the so-called roll-to-roll (R2R) fabrication technique (also known as web processing or reel-to-reel processing) wherein thin-films are deposited on a flexible (plastic) substrate and processed into electrical components in a continuous way. In an R2R process printing techniques (e.g. imprint, inkjet, or screen printing) and coating techniques (e.g. roll, slit coating or spray coating) are used in order to achieve high-throughput, low-cost manufacture of semiconducting devices, including photovoltaic cells and TFT circuitry for displays. Such techniques include the use of inks, i.e. liquid semiconductor, metal and dielectric precursors, which can be deposited on the substrate using a simple coating or printing technique. This way, flexible electronics may be fabricated at a fraction of the cost of traditional semiconductor manufacturing methods.

In order to realize flexible electronics for high-performance applications, such as UHF RFIDs and flexible displays, low-cost and high-throughput formation of high-mobility thin-film semiconductor layers on a flexible substrate is required. Further, the manufacturing process should support formation of structures having small feature size and high alignment accuracy. Commercially interesting candidates for a flexible plastic substrate material include polyethylene naphthalate (PEN) and polyethylene terephthalate (PET). These materials are low-cost materials with a high optical transparency and chemically compatible with most semiconductor processes. The maximum processing temperatures of these materials are however relatively low approximately (approx. 200° C. for PEN and 120° C. for PET).

Several liquid-based techniques for forming a semiconducting coating on a substrate are known. Organic semiconductor materials may be used in a low-temperature deposition technique in order to realize “plastic” TFT circuitry for LCD applications or “plastic” photovoltaic cells. However, the electron mobility and reliability of these organic semiconductors are still inferior to their amorphous silicon counterparts (approx. 1 cm²/Vₛ) so that integration of peripheral driver and control circuits is difficult to achieve. Alternatively, amorphous metal-oxide semiconductors like In-Ga-Zn-O (a-IGZO) may be formed on a plastic substrate using a low-temperature solution-based process. Although, the electron mobility of an a-IGZO layer is higher than a-Si, it is still limited to 20 cm²/Vₛ. Furthermore, the hole mobility is very low so that p-type metal-oxide semiconductor TFTs cannot be made. The inability to realize circuitry in a CMOS configuration poses a serious limitation on the use of this material in commercial applications. Hence, in summary, plastic and a-IGZO semiconducting materials are still substantially inferior to (poly)crystalline silicon / silicon oxide structures that offer highly stable electrical properties and sufficiently high mobility (>100 cm²/Vₛ) for electronics applications. Techniques for liquid-based formation of silicon and silicon dioxide are known. For example, U.S. Pat. No. 6,541,354, EP1284306 and US2003/0229190 describe processes for forming silicon films using a solution containing a cyclic silane compound such as cyclopentasilane (CPS) and a solvent. Typically, the solution is spin-coated onto a substrate and subjected to a drying step in order to remove the solvent. Thereafter, a combined UV treatment and annealing step of the coated substrate at a temperature of around 300° C. is used to transform the coating layer in 30 minutes into an amorphous silicon layer. A further annealing step at 800° C. or exposure of the amorphous silicon layer to laser light may covert the amorphous layer into a poly-crystalline layer. EP1284306 also describes the formation of a silicon dioxde layer by oxidizing a polysilane coating by baking a polysilane coated substrate in an oxygen-environment at a high temperature. Similarly, Tanaka et. al. describe in their article “Solution-processed SiO2 films using hydrogenated polysilane based liquid materials” SID Symposium Digest of Technical Papers, Vol. 38, p. 188-191, May 2007 describe a process wherein SiO2 films are formed on the basis of CPS by backing CPS coatings at temperatures at 410° C. The temperature for forming silicon and silicon dioxide layers on the basis of the liquid-based processes that are known in the prior art are is too high for plastic substrate materials such as PET and PEN.

A further problem relates to the formation of thin-film crystalline structures on the basis of such polysilane coating. WO2013034312 describes process for forming thin-film structures on the basis of a liquid semiconductor precursor. In particular, thin-film structures can be formed by coating the structured substrate with a liquid semiconductor precursor and subsequently annealing the coating. Although small features sizes can be obtained by such method, accurate control of the feature size may be difficult as the process relies on the capillary and/or dewetting properties of the liquid precursor on the surface of the structured substrate.

Hence, there is a need for in the art for fast and efficient low-temperature formation of thin-film structures, in particular silicon and silicon dioxide thin-film structures, using a liquid silicon precursor. In particular, there is a need in the art for efficient low-temperature formation of thin-film semiconductor/semiconductor oxide structures with small feature size on (flexible) substrates using a liquid-based process.

### SUMMARY OF THE INVENTION

It is an objective of the invention to reduce or eliminate at least one of the drawbacks known in the prior art. In a first aspect the invention may relate a method for low-temperature formation of one or more (patterned) thin-film semiconductor structures on a substrate comprising: forming a (poly)silane layer over a substrate; (selectively) transforming one or more parts of said (poly)silane layer in one or more (patterned) thin-film solid-state semiconductor structures by exposing said one or more parts with light from an UV source.

It has been surprisingly found that selective exposure of parts of a (poly)silane layer with UV light allows direct and local transformation of the exposed polysilane into silicon without thermally annealing the substrate (either before or during the transformation) on the basis of a hot bake step or the like. Direct transformation of the (poly)silane into silicon has been achieved by exposing the layer to short UV laser pulses of a predetermined fluence or to UV LED light of a predetermined irradiance. The transformation of the polysilane layer takes place without heating the substrate temperature to temperatures higher than 300° C., preferably higher 250° C., more preferably higher 200° C., even more preferably without heating the temperature of the substrate. Because the (poly)silane is directly transformed into crystalline silicon, the substrate does not need to be subjected to (substrate) annealing temperatures that are higher than the maximum handling temperature of plastic substrates such as polyamide, PEN or PET. Additionally, the process does not require high-vacuum conditions and are compatible with roll-to-roll processing. Moreover, on the basis of the low-temperature formation process described above, silicon structures of different shapes can be formed directly into the polysilane layer without using photoresist and/or a structured substrate. The selective exposure of the (poly)silane layer (e.g. by using an exposure mask or a moving light beam) allows the layer to be exposed to any light pattern wherein the areas of the polysilane layers that are exposed to the light will be directly transformed into patterned thin-film silicon structures.

In an embodiment (selectively) transforming one or more parts of said (poly)silane layer may comprise: illuminating a mask with light from said UV source for transferring a pattern on said mask onto said (poly)silane layer.

In an embodiment (selectively) transforming one or more parts of said (poly)silane layer may comprise: exposing a first part of said (poly)silane layer with light of a first fluence for transforming said first part into a semiconductor with a first crystallinity; exposing a second part of said (poly)silane layer with light of a second fluence for transforming said second part into a semiconductor with a second crystallinity.

In an embodiment, (selectively) transforming one or more parts of said (poly)silane layer may comprise: exposing said one or more parts of said (poly)silane layer by moving a (pulsed) UV light beam of a predetermined size over said (poly)silane layer.

In an embodiment, said method may further comprise: transforming (poly)silane of said layer that is not transformed in a thin-film semiconductor structure into a semiconductor oxide by exposing said (poly)silane to oxygen and/or ozone.

In an embodiment, said method may further comprise: embedding said thin-film solid-state semiconductor structures in an semiconductor oxide by exposing said (poly)silane comprising said thin-film solid-state semiconductor structures to oxygen and/or ozone.

In an embodiment, said method may further comprise: forming a conducting (gate) layer over at least part of at least one of said embedded thin-film solid-state semiconductor structures.

In an embodiment, said light source may be configured for generating one or more wavelengths within the range between 100 and 450 nm.

In an embodiment, the energy density (fluence) and/or irradiance of said UV light source may be selected such that said transformation of said (poly)silane layer takes place without heating the substrate temperature to temperatures higher than 300° C., preferably higher 250° C., more preferably higher 200° C., even more preferably without heating the temperature of the substrate.

In an embodiment, (selectively) transforming one or more parts of said of said (poly)silane layer may comprise:

exposing said one or more parts of said (poly)silane layer to UV light from a (pulsed) laser, preferably, a (pulsed) YAG laser, an argon laser or an excimer laser, preferably the UV light of said (pulsed) laser light having energy density (fluence) between 20 and 1000 mJ/cm2, preferably 25 and 500 mJ/cm2, more preferably between 50 and 400 mJ/cm2. The UV laser based process allows very fast (single pulse) transformation of the polysilane coating directly into a silicon coating.

In an embodiment, (selectively) transforming one or more parts of said of said (poly)silane layer may comprise: exposing said one or more parts of (poly)silane layer to light from a plurality of LED, preferably a LED array, more preferably the light of said a LED array having an irradiance selected between 10 and 1000 mW/cm2, preferably 20 and 800 mW/cm2, more preferably between 40 and 400 mW/cm2. The UV LED based process allows a simple and cheap way of transforming the polysilane coating directly into a silicon coating.

In an embodiment, said (poly)silane layer comprises a silane compound defined by the general formula SiₙXₘ, wherein X is a hydrogen; n is an integer of 5 or greater, preferably an integer between 5 and 20; and m is an integer equal to n, 2n−2, 2n or 2n+1; more preferably said liquid silane compound comprising cyclopentasilane (CPS) and/or cyclohexasilane; or, wherein said (poly)silane layer comprises a silane compound defined by the general formula SiᵢXⱼYₚ, wherein X represents a hydrogen atom and/or halogen atom and Y represents an boron atom or a phosphorus atom; wherein i represents an integer of 3 or more; j represents an integer selected from the range defined by i and 2i+p+2; and, p represents an integer selected from the range defined by 1 and I; or, wherein said (poly)silane layer comprises neopentasilane.

In an embodiment said (poly)silane layer may be formed on said substrate by applying a substantially pure liquid (poly)silane on said substrate.

In an embodiment, said substrate may be a polymer-based substrate, a paper- or cellulose based substrate, a (woven or non-woven) fibre-based substrate, preferably said polymer-based substrate comprising polyimide, PEN or PET or derivatives thereof. The (poly)silane is directly transformed into crystalline silicon or silcon oxide so that the substrate does not need to be subjected to annealing temperatures that are higher than the maximum handling temperature of plastic substrates such as polyamide, PEN or PET.

In an embodiment, said (poly)silane layer may be formed on said substrate using a printing technique, preferably ink jet printing, gravure printing, screen printing, flexographic/letterpress printing and/or offset printing.

In an embodiment said printing technique may be used to form a patterned (poly)silane layer on said substrate.

In an embodiment, a coating technique, preferably doctor blade coating, slot die coating, roller coating, dip coating and/or air knife coating technique, may be used for forming a continuous (poly)silane layer on said substrate.

In a further aspect, the invention may relate to the use of the method as described above in the manufacturer of a semiconducting device, preferably a thin-film transistor, an LCD structure, a memory cell or a photovoltaic cell.

In a further aspect, the invention may relate to a thin-film semiconductor structure comprising: a substrate; a continuous thin-film layer on said substrate wherein said thin-film layer comprises one or more thin-film semiconductor structures and one or more thin-film (poly)silane structures and wherein the top surface of said continuous thin-film layer is substantially planar.

In an embodiment, a first semiconductor structure of said one or more thin-film semiconductor structures may have a first crystallinity and a second semiconductor structure of said one or more thin-film semiconductor structures may have a second crystallinity.

In a further aspect, the invention may relate to a semiconductor structure comprising: a substrate; a continuous thin-film layer on said substrate wherein said thin-film layer comprises one or more thin-film semiconductor structures, preferably one or more patterned thin-film crystalline silicon structures, and one or more thin-film patterned semiconductor oxide structures wherein said one or more thin-film semiconductor structures are embedded in said one or more thin-film semiconductor oxide structures and wherein the top surface of said continuous thin-film layer is substantially planar.

The invention will be further illustrated with reference to the attached drawings, which schematically will show embodiments according to the invention. It will be understood that the invention is not in any way restricted to these specific embodiments.

### BRIEF DESCRIPTION OF THE DRAWINGS

FIG. 1A-1C depict a low-temperature process for liquid-based formation of silicon layer according to an embodiment of the invention.

FIG. 2A-2C depict AFM measurements and a Raman spectrum of a poly-silicon thin film has have been fabricated using low-temperature processes according to various embodiments of the invention.

FIG. 3A-3D depict Raman spectra of poly-silicon thin films that have been fabricated using solution-based silicon formation processes according to various embodiments of the invention.

FIG. 4A-4C depict further Raman spectra of silicon layers that have been fabricated using solution-based silicon formation processes according to various embodiments of the invention.

FIG. 5A and 5B show the formation of crystalline/amorphous structures in a polysilane coating according various embodiments of the invention.

FIG. 6A-6F depicts a (cross-sectional view of a) process for fabrication part of a semiconductor device according to an embodiment of the invention.

FIG. 7A and 7B depicts a conventional TFT and a TFT that is fabricated on the basis of the low-temperature processing of polysilane.

FIG. 8A and 8B illustrate the formation of a gate electrode according to an embodiment of the invention.

### DETAILED DESCRIPTION

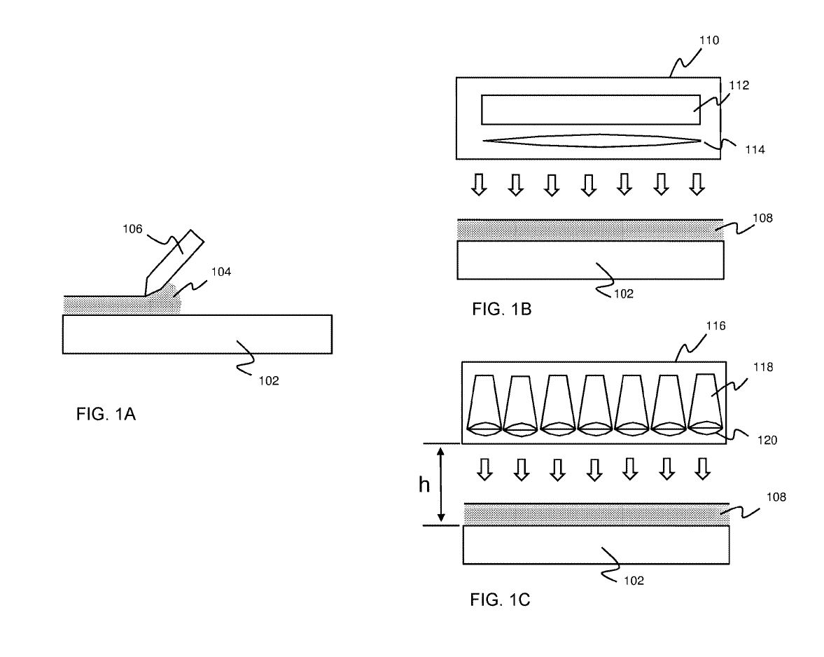

FIG. 1A-1C depict a low-temperature process for liquid-based formation of a silicon layer according to an embodiment of the invention. As shown in FIG. 1A, a substrate 102 may be coated with a liquid silane compound 104 using suitable coating technique, e.g. a doctor-blade or a spin coating technique in a low-oxygen environment (below 10 ppm, more preferably below 1 ppm) wherein a doctor blade 106 is used for smoothly applying a silane coating on the top surface of the substrate. Instead of doctor blade coating technique other coating techniques including e.g. slot die coating, roller coating, dip coating, air knife coating, etc. may be used to apply the silane on the substrate.

Alternatively, a printing technique such gravure printing, screen printing, flexographic/letterpress printing, ink jet printing and/or offset printing may be used to apply a silane layer the substrate. In that case, the silane layer may be have a particular printing pattern. For example, when using an ink jet printer for depositing a silane layer on the substrate, the ink jet printer may print a particular patterned silane layer on the substrate.

Preferably, the substrate may comprise a flexible plastic substrate material including for example a polyamide, polyethylene naphthalate (PEN) and/or polyethylene terephthalate (PET). Alternatively and/or in addition, the substrate may comprise a flexible substrate material including cellulose-based material and/or a (woven or a non-woven) fibre-based material.

In an embodiment, the liquid silane may comprise cyclopentasilane (CPS) Si₅H₁₀. In an embodiment, the CPS may be irradiated with UV radiation for a predetermined time. The UV radiation may be used in order to break the CPS rings and to transform at least part of the CPS in (low-order) polysilanes, which are soluble in the CPS. Hence, by UV irradiating the CPS coating a coating may be formed comprising polysilane or a mixture of polysilane and CPS (a cyclic silane). For the purpose of this disclosure, a polysilane coating or a mixed polysilane-cyclic silane coating will be referred to as a polysilane coating.

In an embodiment, the CPS may be irradiated with an UV light source for generating UV light having an intensity selected between 1 and 100 mW, preferably between 2 and 50 mW, more preferably between 5 and 20 mW. Depending on the selected intensity and the desired degree of polymerization, the coating may be exposed to UV light for a period between 1 and 100 minutes, preferably between 2 and 50 minutes, more preferably between 5 and 40 minutes. The polymerization process transforms the CPS into a polysilane coating or a mixed polysilane-CPS coating that is more viscous and more stable for handing in subsequent processing steps. Moreover, the formation of polysilane increases the boiling temperature of the coating so that the coating can be annealed at temperatures higher than the boiling temperature of CPS (which is around 194° C.).

The thickness of the polysilane thin-film layer may be selected between 50 and 5000 nm, preferably between 50 and 4000 nm, more preferably between 50 and 2000 nm or between 50 and 1000 nm.

While the examples in this application are described with reference to cyclopentasilane (CPS) Si₅H₁₀, the invention is by no limited to this material. In particular, the invention may be used with liquid semiconductor precursors comprising one or more silane compounds. In an embodiment, a silane compound may be represented by the general formula SiₙXₘ, wherein X is a hydrogen; n is preferably an integer of 5 or greater and is more preferably an integer between 5 and 20; m is preferably an integer of n, 2n−2, 2n or 2n+1; wherein part of the hydrogen may be replace by a halogen.

Examples of such silane compounds are described in detail in EP1087428, which is hereby incorporated by reference into this application. Examples of the compounds of m=2n+2 include silane hydrides, such as trisilane, tetrasilane, pentasilane, hexasilane, and heptasilane, and substituted compounds thereof in which hydrogen atoms are partially or completely replaced with halogen atoms. Examples of m=2n include monocyclic silicon hydride compounds, such as cyclotrisilane, cyclotetrasilane, cyclopentasilane, silylcyclopentasilane, cyclohexasilane, silylcyclohexasilane, and cycloheptasilane; and halogenated cyclic silicon compounds thereof in which hydrogen atoms are partially or completely replaced with halogen atoms, such as hexachlorocyclotrisilane, trichlorocyclotrisilane, coctachlorocyclotetrasilane, tetrachlorocyclotetrasilane, decachlorocyclopentasilane, pentachlorocyclopentasilane, dodecachlorocyclohexasilane, hexachlorocyclohexasilane, tetradecachlorocycloheptasilane, heptachlorocycloheptasilane, hexabromocyclotrisilane, tribromocyclotrisilane, pentabromocyclotrisilane, tetrabromocyclotrisilane, octabromocyclotetrasilane, tetrabromocyclotetrasilane, decabromocyclopentasilane, pentabromocyclopentasilane, dodecabromocyclohexasilane, hexabromocyclohexasilane, tetradecabromocycloheptasilane, and heptabromocycloheptasilane. Examples of compounds of m=2n-2 include dicyclic silicon hydride compounds, such as 1,1′-biscyclobutasilane, 1,1′-biscyclopentasilane, 1,1′-biscyclohexasilane, 1,1′-biscycloheptasilane, 1,1′-cyclobutasilylcyclopentasilane, 1,1′-cyclobutasilylcyclohexasilane, 1,1′-cyclobutasilylcycloheptasilane, 1,1′-cyclopentasilylcyclohexasilane, 1,1′-cyclopentasilylcycloheptasilane, 1,1′-cyclohexasilylcycloheptasilane, spiro[2,2]pentasilane, spiro[3,3]heptasilane, spiro[4,4]nonasilane, spiro[4,5]decasilane, spiro[4,6]undecasilane, spiro[5,5]undecasilane, spiro[5,6]dodecasilane, and spiro[6,6]tridecasilane; substituted silicon compounds in which hydrogen atoms are partly or completely replaced with SiH3 groups or halogen atoms. Moreover, examples of compounds of m=n include polycyclic silicon hydride compounds, such as Compounds 1 to 5 represented by the following formulae, arid substituted silicon compounds thereof in which hydrogen atoms are partially or completely replaced with SiH3 groups or halogen atoms. These compounds may be used as a mixture of two or more types.

In an embodiment, the liquid silane compound may comprise a cyclic silane, such as cyclopentasilane (CPS) Si₅H₁₀ and/or cyclohexasilane (CHS) Si₆H₁₂. In another embodiment, the liquid silane compound may comprise neopentasilane.

In an embodiment, a substantially pure liquid silane compound or a mixture of at least two substantially pure liquid silane compounds may be used in the formation of a polysilane coating on a substrate. In an embodiment “substantially pure” may refer to a purity level of a liquid semiconducting precursor of 94%, 96%, 98% or higher than 99%.

The polysilane coating may then be transformed into a solid-state silicon layer by exposing the coating to UV light. In an embodiment, polysilane coating may be transformed directly, i.e. without any thermal annealing step (e.g. a hot plate anneal), in silicon by exposing the polysilane layer to UV radiation for a predetermined time.

FIG. 1B depicts a process wherein the substrate 102 comprising the polysilane coating 108 is exposed to UV light originating from a UV laser system 110. The UV laser system may comprise a UV laser and an optical system 114 for focussing the laser light onto the coating.

The laser light has a wavelength selected within the UV range, e.g. between 100 and 450 nm, preferably between 200 and 400 nm. Examples of such UV laser include but are not limited to excimer lasers, YAG lasers, argon lasers, etc. The

UV laser may be configured to transmit short pulses of laser light in the UV spectrum. In an embodiment, the pulse width may be selected between 5 and 500 nm. In another embodiment, a laser pulse may have an energy density (fluence) selected between 20 and 1000 mJ/cm2, preferably 25 and 500 mJ/cm2, more preferably between 50 and 400 mJ/cm2.

Hence, in an embodiment, UV laser light pulses may be used to directly transform the polysilane into silicon. As will be shown hereunder in greater detail, depending on the fluence and the number of pulses the polysilane layer may be transformed in different types of silicon layers, including amorphous, microcrystalline, nanocrystalline and/or polycrystalline silicon.

FIG. 1C depicts a process wherein the substrate 102 comprising the polysilane coating 108 is exposed to UV light originating from a UV LED array system 116. The UV LED array system may comprise a plurality of UV LEDs 118 wherein each LED is associated with an optical lens and/or reflector system 120 such that the LED array irradiates a substantial homogenous beam of UV light of a predetermined intensity onto the substrate. In an embodiment, the UV LED array may be configured to generate an irradiance selected between 100 and 800 mW/cm2, preferably 200 and 700 mW/cm2 and the UV LED array may be positioned at a 25-100 mm distance from the substrate surface. Further, the LEDs may be configured to generate UV light in range selected between 100 and 450 nm, preferably between 200 and 400 nm.

In case patterned polysilane layer formed on the substrate, e.g. using a (ink jet) printing technique, patterned silicon structures may be realized on the basis of the low-temperature process depicted in FIG. 1A-1C without the need of resist and/or etching techniques.

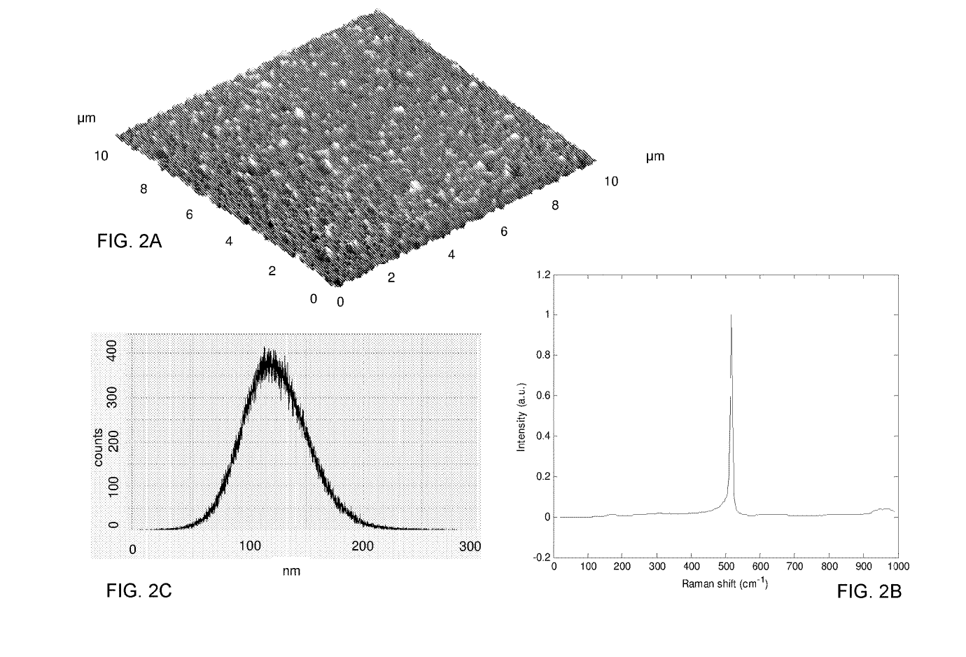

FIG. 2A-2C depict AFM measurements and a Raman spectrum of polysilicon thin films that have been formed by exposing a polysilane coating to laser as described with reference to FIG. 1B. In this particular example, the coating is irradiated with 50 laser pulses of a fluence of 250 mJ/cm2.

The associated Raman spectrum shows the formation of a high quality polysilicon layer. The AFM measurements indicate an average grain size of 124 nm and an average roughness of 23 nm. The grain size can be controlled by the number of pulses.

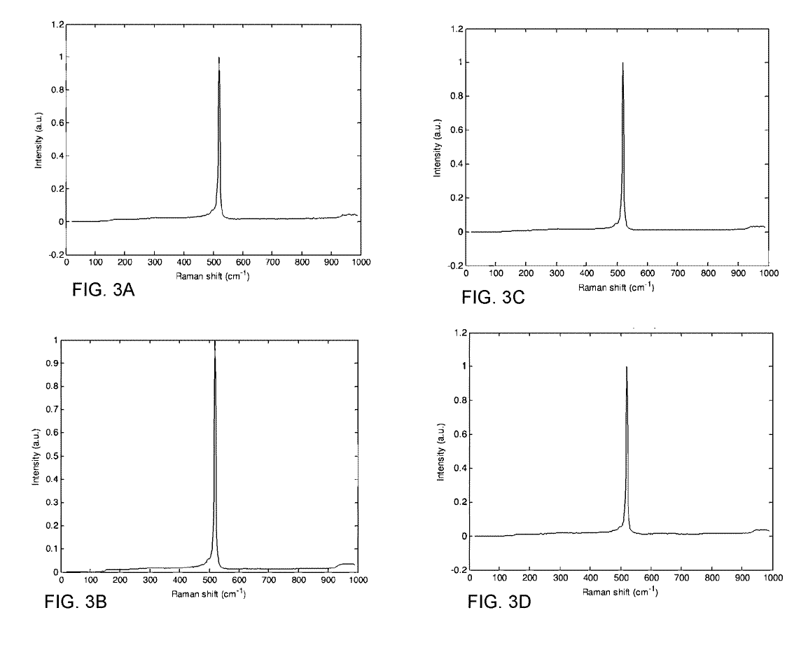

FIG. 3A-3D show Raman spectra of silicon thin-films that are formed by a exposing polysilane coating to a single UV laser pulse (in this particular case an XeCl excimer laser, 25 ns pulse width at 308 nm) for increasing energy densities: FIG. 3A shows the result of the exposure of the polysilane coating using a single shot laser pulse of 150 mJ/cm2; FIG. 3B shows the result of the exposure of the polysilane coating using a single shot laser pulse of 200 mJ/cm2; FIG. 3C shows the result of the exposure of the polysilane coating using a single shot laser pulse of 250 mJ/cm2 and FIG. 3D shows the result of the exposure of the polysilane coating using a single shot laser pulse of 300 mJ/cm2. These results show that polycrystalline layers are obtained by exposing a polysilane coating with pulsed laser light of an energy density selected between 150 and 300 mJ/cm2 wherein the polysilane coating was not subjected to a temperature annealing step before the laser exposure. Different number of pulses may be used ranging from one to up to 400, preferably 200 pulses.

When using pulsed laser light in the UV range, the layers can be effectively instantaneously transformed into solid-state silicon on the basis of only one or more very short pulses. Such laser pulses may have a pulse width within 10-500 ns, hence the transformation of the (poly)silane compounds occurs at a very short time-scale, thus providing a very fast and efficient process of forming silicon on the basis of a (poly)silane coating. Hence, the time for transforming the coating depends on the pulse width and the number of pulses that are used for the transformation. Hence, when using only one pulse the (poly)silane coating may be transformed into a solid state silicon within 10-500 ns. Alternatively, when using multiple pulses, the transformation time approximately equals the pulse width times the number of pulses.

Similar Raman spectra were obtained when exposing polysilane coatings to UV radiation originating from an UV LED array as described with reference to FIG. 1C. In particular, the spectra show the formation of polycrystalline silicon films by exposing the coating for 20-40 minutes to an UV irradiance selected between 100 and 400 mW/cm2, preferably between 150 and 350 mW/cm2.

It has been surprisingly found that one or more layers of silane compounds (e.g. coating of one or more silane compounds) can be directly transformed by UV light into silicon without thermally annealing the substrate (either before or during the transformation). Direct transformation of the (poly)silane into silicon has been achieved by exposing the layer to UV laser pulses of a predetermined energy density to UV LED light of a predetermined irradiance. Because the (poly)silane is directly and substantially instantaneously transformed into amorphous or crystalline silicon the substrate does not need to be subjected to annealing temperatures that are higher than the maximum handling temperature of the substrate, in particular plastic substrates such as polyamide, PEN or PET. Such process is very suitable for using in high throughput processing.

The low-temperature process based on pulse laser light allows direct, very fast (even single pulse) transformation of the polysilane coating into a silicon coating. The UV LED based process allows a simple and cheap way of directly transforming the polysilane coating into a silicon coating. In any way, both processes do not require high-vacuum conditions and are compatible with roll-to-roll processing.

The low-temperature solution-based process described with reference to FIG. 1-3 thus allows the formation of solid-state silicon (polycrystalline, nanocrystallince or microcrystalline silicon or amorphous silicon) on flexible substrates, including plastic substrates that have a relative low processing temperature (e.g. PET or PEN), a cellulose-based material and/or a (woven or a non-woven) fibre-based substrate material.

In a further embodiment, the solution-based low-temperature process described above may also be used for forming silicon-dioxide (SiO₂) on a flexible substrate. In this process, polysilane may be coated onto a substrate in a similar way as described with reference to FIG. 1A. Thereafter, the polysilane coating may be transformed into silicon oxide by exposing the coating to oxygen and/or ozone for a predetermined time. The oxidation time may be selected between 10 and 120 min, preferably between 20 and 60 min.

The oxidation process may be accelerated by heating the substrate up to a temperature that is below the maximum handling temperature of the substrate material. In an embodiment, the substrate may be heated to a temperature between 100 and 300° C. In another embodiment, the substrate may be heated up to a temperature selected between 100 and 250° C. In yet another embodiment, the substrate may be heated up to a temperature selected between 100 and 200° C.

Alternatively and/or in addition, the oxidation process may be accelerated by exposing the polysilane layer to UV light of an UV source during the oxidation step. In particular, during and/or after the oxidation process, the polysilane layer may be exposed to UV light. Preferably, an UV LED system as described with reference to FIG. 1C is used exposing the polysilane layer during the oxidation process. In an embodiment, the UV LED array may be configured to generate an irradiance selected between 10 and 1000 mW/cm2, preferably 20 and 800 mW/cm2, more preferably between 40 and 400 mW/cm2. During exposure, the UV LED array may be positioned at a predetermined distance from the substrate surface. The distance may be selected between 10 and 1000 mm, preferably between 25 and 100 mm. This way a silicon oxide film may be formed.

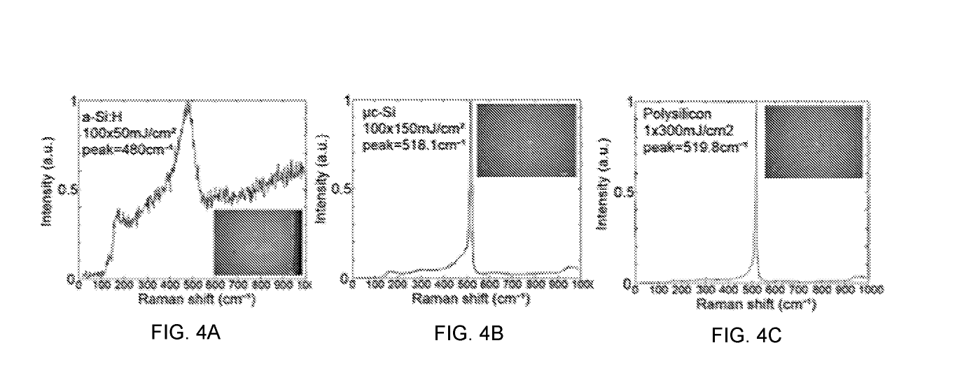

FIG. 4A-4C depict further Raman spectra of silicon layers that have been fabricated using solution-based silicon formation processes according to various embodiments of the invention. In particular, Fig. FIG. 4A-4C show further results of the direct transformation of a polysilane layer into a silicon layer by exposing a polysilane layer to UV light. In these examples substantially pure cyclopentasilane (CPS) was coated over the substrate at an elevated substrate temperature of 80° C. using a doctor blade in an oxygen-free environment.

The CPS was polymerized into a polysilane solution by exposing the layer to UV light for 30 minutes at a temperature of 100° C. Thereafter the polysilane coating was directly crystallized by exposing the coating to pulsed laser light of an XeCl excimer laser (308 nm, 28ns). As shown in the Raman spectra of FIG. 4A-4C, depending on the energy density and the number of laser pulses, the polysilane coating directly transforms into a-Si (100 pulses of 50 mJ/cm²), μc-Si (100 pulses of 150 mJ/cm² or poly-Si (one pulse of 50 mJ/cm²). More in general, low energy density pulses led to the formation of an a-Si:H film, whereas higher energy densities lead to crystallization of the polysilane film.

On the basis of the low-temperature formation process described above, silicon structures of different shapes can be formed directly into the polysilane layer without using photoresist and/or a structured substrate. Typically, the fluence of the pulse is selected between 10 and 1000 mW/cm2, preferably 20 and 800 mW/cm2, more preferably between 40 and 400 mW/cm2 and the number of pulses is selected between 1-400, preferably 1 and 200. In some embodiments, exposure is realized by selecting a first number of pulses of a first fluence and a second number of pulses of a second fluence.

As will be shown hereunder in more detail, crystalline structures with small feature size can be formed in the polysilane layer in a very efficient way.

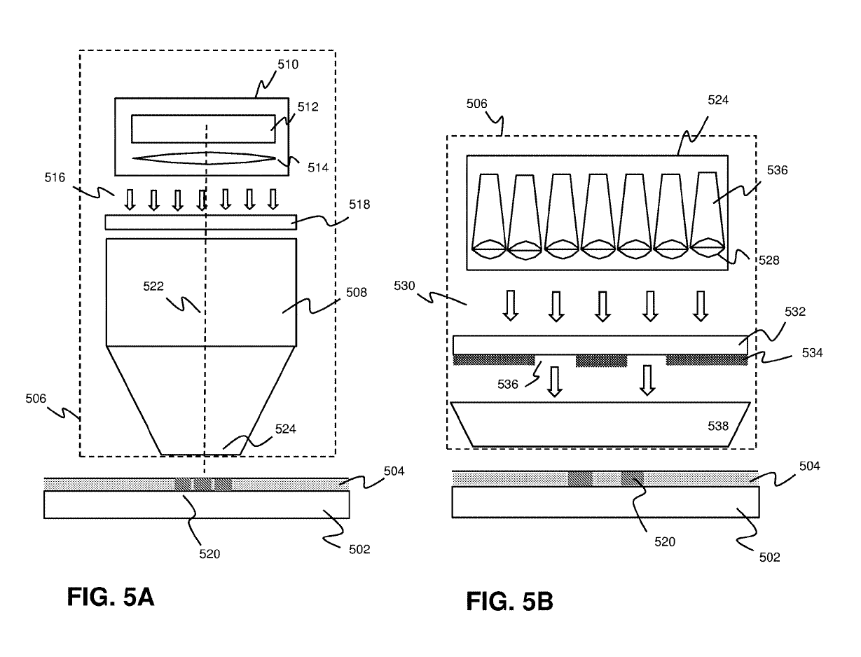

FIG. 5A and 5B show the formation of crystalline/amorphous structures in a polysilane coating according various embodiments of the invention. FIG. 5A depicts an optical projection exposure system for selectively exposing and transforming areas of the polysilane coating into crystalline/amorphous silicon structures.

The projection exposure system may comprise an exposure UV light source 510 comprising an UV laser 512, e.g. an excimer laser, for exposing a mask 518 with ultraviolet light 516 and an optical system 514,508 that is configured to transfer a mask pattern into the polysilane layer 504. The optical system may comprise optical elements, e.g. an optical integrator (a homogenizer), field stops, a condenser lens, etc. so that the mask is illuminated with a homogenous light beam and so that light passing the mask is reduced and projected onto the surface of the polysilane coating under a certain projection magnification.

The substrate (wafer) 502 comprising the polysilane coating 504 may be placed in holder that is positioned in line with the optical axis 522 (z-axis) of the optical system. Both the mask and the substrate may be mounted on a holder that is movable in the plane that is perpendicular to the optical axis (i.e. the plane defined by the x-axis and y-axis) so during the exposure system different exposure patterns of the mask can be used to exposure different areas of the polysilane layer. Light that exits the optical system at the exit of the optical system illuminates areas 520 in the polysilane coating so that these areas are transformed into crystalline silicon. This way, crystalline silicon areas are formed in the polysilane coating that have a shape that is determined by the mask pattern.

State of the art UV projection exposure systems as shown in FIG. 5A can easily produce small submicron features between 200 and 500 nm. Furthermore, during the transfer (of parts) of the mask pattern onto the polysilane layer, different fluences and/or different number of pulses may be used to expose the polysilane coating layer. This way, one or more areas a first crystalline composition (e.g. amorphous, micro- or nanocrystalline, polycrystalline) and one or more areas of a second crystalline composition (e.g. amorphous, micro- or nanocrystalline, polycrystalline) that is different from the first crystalline composition may be formed in the polysilane layer. This way, in one polysilane layer silicon structures of different crystallinity/grain size may be formed.

FIG. 5B depicts another optical projection exposure system that can be used for forming crystalline silicon areas of a predetermined shape in the polysilane coating. In this embodiment, the projection exposure system may comprise a UV light source comprising a UV LED array system 116. The UV LED array system may comprise a plurality of UV LEDs 118 wherein each LED is associated with an optical lens and/or reflector system 120 such that the LED array irradiates a substantial homogenous beam of UV light of a predetermined intensity onto the substrate. In an embodiment, the UV LED array may be configured to generate an irradiance selected between 100 and 800 mW/cm2, preferably 200 and 700 mW/cm2 and the UV LED array may be positioned at a 25-100 mm distance from the substrate surface. Further, the LEDs may be configured to generate UV light in range selected between 100 and 450 nm, preferably between 200 and 400 nm.

The light source may generate UV light 530 for illuminating a mask 532 comprising non-transparent regions 534 and transparent regions 536. Optionally, the light that passes through the mask may be projected by an optical system 538 on the polysilane layer. Light that passes the mask illuminates areas 520 in the polysilane coating so that these areas are transformed into crystalline silicon. This way patterns on the mask can be transferred onto the polysilane layer wherein the areas of the polysilane layers that are exposed to the light will be directly transformed into silicon. The UV LED based projection exposure allows a simple and cheap way of transforming the polysilane coating directly into a silicon coating.

Hence, the projection exposure systems of FIG. 5A and 5B allow fast and efficient formation of patterned thin-film amorphous and/or crystalline structures in the polysilane layer. Instead of (static) exposure of the polysilane layer, local formation of patterned thin-film amorphous and/or crystalline structures may also be achieved by exposing one or more parts of said (poly)silane layer with UV light by moving a (pulsed) UV light beam of a predetermined size over said (poly)silane layer. This way, it is possible to directly “write” patterned thin-film silicon structures in the polysilane layer.

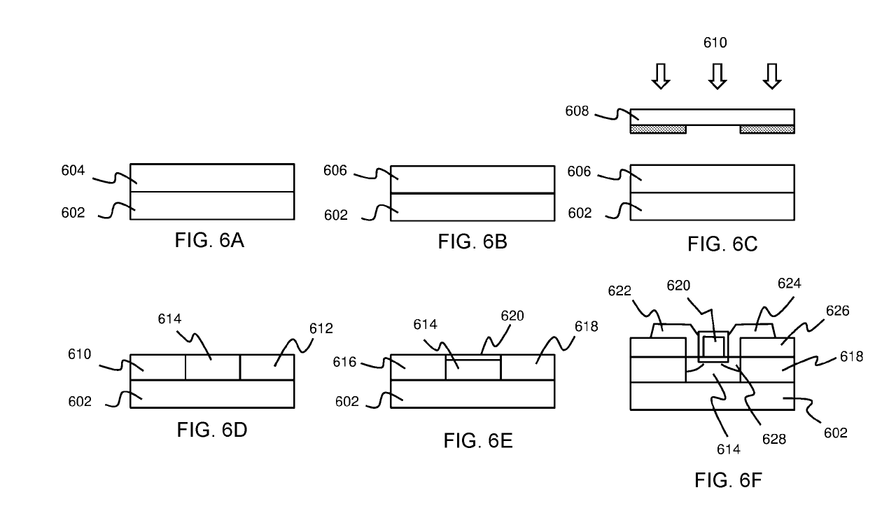

FIG. 6A-6F depicts a (cross-sectional view of a) process for fabrication part of a semiconductor device according to an embodiment of the invention. The process may start with applying a CPS coating 604 onto a substrate 602 on the basis of a suitable coating technique (FIG. 6A), transforming at least part of the CPS layer in a polysilane layer 606 by exposing the CPS layer to UV light 610 (FIG. 6B) and selectively exposing areas of polysilane layer to UV light of a suitable UV source (FIG. 6C), e.g. a laser or a led array, in order to directly transform the exposed one or more areas 614 into a silicon of a particular crystallinity (e.g. amorphous, micro- or nanocrystalline or polycrystalline). In case the substrate (wafer) comprising the polysilane coating is much larger than the area that can be processed by the optical projection system the process steps of FIG. 6C may be repeated serveral times by moving substrate relative to the optical exposure apparatus. This way silicon areas can be formed over the whole area of the polysilane coating. The resulting structure thus comprises a layer on a substrate comprising one or more polysilane areas 610,612 and one or more patterned silicon areas 614. The silicon areas may be patterned such that they form part of a semiconductor device (e.g. a gate structure or a channel).

Thereafter, the layer comprising the polysilane areas and the silicon areas may be subjected to an oxidation step as shown in FIG. 6E. During the oxidation process, the polysilane and the surface of the silicon areas that are exposed to the oxygen may be transformed into silicon oxide. This way, the thin-film polysilane structures are transformed into thin-film silicon oxide structures 616,618 and a thin thermal oxide layer 620 is formed over the top surface of the thin-film silicon structures. In an embodiment, the thin oxide layer may be used as a gate oxide layer of a transistor. The oxidation process may be realized by exposing the layer to oxygen and/or ozone for a predetermined time. The oxidation time may be selected between 10 and 120 min, preferably between 20 and 60 min.

The oxidation process may be accelerated by heating the substrate up to a temperature that is below the maximum handling temperature of the substrate material. In an embodiment, the substrate may be heated to a temperature between 100 and 300° C. In another embodiment, the substrate may be heated up to a temperature selected between 100 and 250° C. In yet another embodiment, the substrate may be heated up to a temperature selected between 100 and 200° C.

Alternatively and/or in addition, the oxidation process may be accelerated by exposing the layer to UV light of an UV source 506 during the oxidation step. In particular, during and/or after the oxidation process, the polysilane layer may be exposed to UV light. Preferably, an UV LED system as described with reference to FIG. 1C may be used exposing the polysilane layer during the oxidation process.

In an embodiment, the UV LED array may be configured to generate an irradiance selected between 10 and 1000 mW/cm2, preferably 20 and 800 mW/cm2, more preferably between 40 and 400 mW/cm2. During exposure, the UV LED array may be positioned at a predetermined distance from the substrate surface. The distance may be selected between 10 and 1000 mm, preferably between 25 and 100 mm.

Hence, after the oxidation process, a thin-film structure is formed on the substrate wherein the silicon structure is embedded in the silicon oxide. The embedded silicon/silicon oxide structure as shown in FIG. 6E may be further processed in order to form a thin-film transistor structure wherein the silicon structure 614 may be used as the transistor channel and the oxide layer over the silicon structure as a gate oxide.

Based on further TFT processing steps the embedded silicon/silicon oxide structure may be processed into a transistor structure comprising a channel 614 that is in electrical contact to a source and drain contacts 622,624. Doped regions in the 628 in the silicon channel structure allow Ohmic contact to the source and drain contacts. Further, the silicon oxide layer that was formed by oxidizing the polysilane into silicon oxide electrically isolates the silicon channel from other parts of the device. A polysilicon gate 620 may be formed on top of the thin silicon oxide gate isolation layer that was formed during the oxidation of the silicon/polysilane structure (as shown in FIG. 6E).

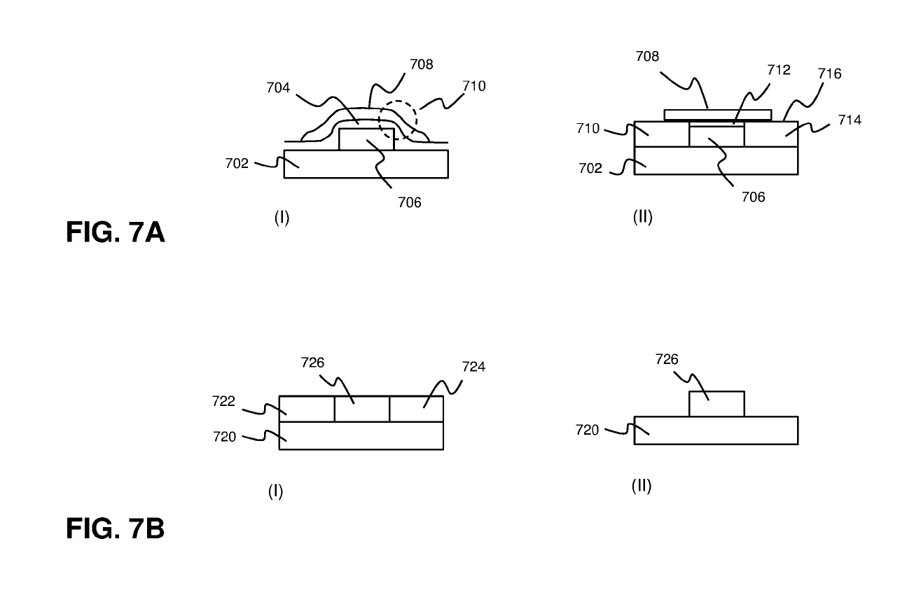

The embedded silicon/silicon oxide structure as shown in FIG. 6E is particular suitable for forming thin-film transistor structures as the top surface of the embedded silicon/silicon oxide structure is substantially flat. These advantages are illustrate in FIG. 7A (I) and (II). FIG. 7A (I) depicts a conventional thin-film transistor structure comprising a channel structure 702 on a substrate 706. A silicon oxide layer is formed over the channel layer in order to form a gate insulation layer 704 which electrically isolates the channel structure 706 from a gate layer 708. As shown in the figure, the conventional TFT structure will suffer from electric field concentration at the edges 710 of the silicon channel. This electric field concentration may result in leakage currents thereby negatively influencing the power-consumption of the end product in which the TFTs are used (e.g. a flat-panel display). The embedded silicon/silicon oxide structure shown in FIG. 7A (II) does not suffer from such electric field concentration problem due to the fact that the silicon structures 706 and the silicon oxide structures 710,714,712 are formed in the same polysilane layer such that step-coverage problems as depicted in FIG. 7A (I) will not appear. Furthermore, the top surface 716 of the layer comprising the embedded silicon/silicon oxide structures is substantially planar so that the formation of the gate electrode 708 over the silicon channel 706 is much easier.

Hence, as shown in FIG. 7A, invention allows the formation of a semiconductor structure that comprises a substrate; and a continuous thin-film layer on said substrate, wherein the thin-film layer comprises one or more patterned thin-film crystalline silicon structures and one or more thin-film patterned semiconductor oxide structures, wherein the one or more thin-film semiconductor structures are embedded in said one or more thin-film semiconductor oxide structures and wherein the top surface of the continuous thin-film layer is substantially planar. Because the crystalline silicon structures and the semiconductor oxide structures are formed on the basis of one single continuous (poly)silane layer, the resulting thin-film structure has substantial advantageous over the conventional thin-film semiconductor/semiconductor oxide structures that are formed on the basis of forming thin-film layers over each other.

FIG. 7B (I) and (II) depicts a (cross-sectional view of a) process for fabrication part of a semiconductor using the low-temperature formation of silicon on the basis of a polysilane coating according to another embodiment of the invention. In this embodiment, a substrate 702 comprising a layer comprising one or more silicon areas 706 and one or more polysilane areas 704,708 (FIG. 7B (I)) may be formed in a similar way as described in detail with reference to FIG. 6A-6D. Thereafter, instead of subjecting the layer to an oxidation step as shown in FIG. 6E, the polysilane areas 704,708 may be removed using a suitable annealing step which effectively evaporates the polysilicon or by dissolving the polysilane using a suitable solvent. During the removal of the polysilane, the silicon structures 706 will remain on the substrate resulting in a thin-film silicon structure as shown in FIG. 7B (II).

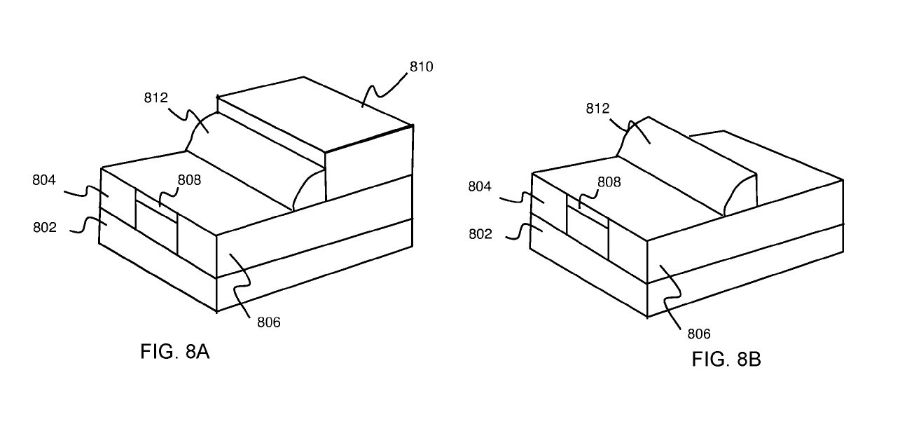

FIG. 8A and 8B illustrate the formation of a gate electrode according to an embodiment of the invention. In particular, FIG. 8A and 8B depict the formation of a polysilicon gate electrode over a silicon channel that is embedded in a silicon layer. These figures show the embedded silicon/silicon oxide structure as discussed with reference to FIG. 6 comprising a substrate 802, a silicon channel and silicon dioxide structures 804,806,808 beside and over the silicon channel. The top surface of the embedded silicon/silicon oxide structure will be substantially planar since these silicon and silicon dioxide structures are formed by UV exposure and subsequent oxidation of one polysilane layer. For example, due to the planar surface, it becomes possible to form a polysilicon gate structure 806 by using dewetting properties of polysilsane which results in accumulation of polysilane along the sidewall of a patterned sacrificial layer 810. After removal of the described in detail in sacrificial layer, a polysilicon gate may be formed that has submicron dimensions. Such process is described in detail in WO2014/120001 which is incorporated by reference into this application.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

It is to be understood that any feature described in relation to any one embodiment may be used alone, or in combination with other features described, and may also be used in combination with one or more features of any other of the embodiments, or any combination of any other of the embodiments. The invention is not limited to the embodiments described above, which may be varied within the scope of the accompanying claims. For example, different coating and/or printing techniques may be used to apply a polysilane layer onto a substrate. Exemplary printing techniques that may be used with the invention include gravure printing, screen printing, flexographic/letterpress printing and/or offset printing. Similarly, exemplary coating techniques that may be used include slot die coating, roller coating, dip coating, air knife coating, etc. Further, other (flexible) substrates than plastic substrates may be used as a support substrate including metallic, fibre-type (woven or non-woven) sheets, etc.

1. A method for low-temperature formation of one or more thin-film semiconductor structures on a substrate comprising:
forming a (poly)silane layer over a substrate;
transforming one or more parts of said (poly)silane layer in one or more thin-film solid-state semiconductor structures by exposing said one or more parts with light from an UV source.

2. The method according to claim 1 wherein selectively transforming one or more parts of said (poly)silane layer comprises:
illuminating a mask with light from said UV source for transferring a pattern on said mask onto said (poly)silane layer.

3. The method according to claim 1 wherein transforming one or more parts of said (poly)silane layer comprises:
exposing a first part of said (poly)silane layer with light of a first fluence for transforming said first part into a semiconductor with a first crystallinity;
exposing a second part of said (poly)silane layer with light of a second fluence for transforming said second part into a semiconductor with a second crystallinity.

4. The method according to claim 1 wherein transforming one or more parts of said (poly)silane layer comprises:
exposing said one or more parts of said (poly)silane layer by moving a (pulsed) UV light beam of a predetermined size over said (poly)silane layer.

5. The method according to claim 1 further comprising:
transforming (poly)silane of said layer that is not transformed in a thin-film semiconductor structure into a semiconductor oxide by exposing said (poly)silane to oxygen.

6. The method according to claim 1 further comprising:
embedding said thin-film solid-state semiconductor structures in an semiconductor oxide by exposing said (poly)silane comprising said thin-film solid-state semiconductor structures to oxygen.

7. The method according to claim 6 further comprising forming a conducting (gate) layer over at least part of at least one of said embedded thin-film solid-state semiconductor structures.

8. The method according to claim 1 wherein said UV source is configured for generating one or more wavelengths within the range between 100 and 450 nm.

9. The method according to claim 1 wherein the energy density (fluence) of said UV light source is selected such that said transformation of said (poly)silane layer takes place without heating the temperature of the substrate.

10. The method according to claim 1 wherein transforming one or more parts of said of said (poly)silane layer comprises:
exposing said one or more parts of said (poly)silane layer to UV light from a (pulsed) laser.

11. The method according to claim 1 wherein transforming one or more parts of said of said (poly)silane layer comprises:
exposing said one or more parts of (poly)silane layer to light from a LED array, having an irradiance selected between 40 and 400 mW/cm2.

12. The method according to claim 1
wherein said (poly)silane layer comprises a silane compound defined by the general formula SiₙXₘ, wherein X is a hydrogen; n is an integer of 5 or greater and m is an integer equal to n, 2n−2, 2n or 2n+1.

13. The method according to claim 1 wherein said (poly)silane layer is formed on said substrate by applying a substantially pure liquid (poly)silane on said substrate.

14. The method according to claim 1 wherein said substrate is a polymer-based substrate, a paper or cellulose based substrate, a fibre-based substrate, PEN or PET or derivatives thereof.

15. The method according to claim 1 wherein said (poly)silane layer is formed over said substrate using a printing technique.

16. The method according to claim 15 wherein said printing technique is used to form a patterned (poly)silane layer on said substrate.

17. The method according to claim 1 wherein a coating technique is used for forming a continuous (poly)silane layer on said substrate.

18. Use of the method according to claim 1, in the manufacturer of a semiconducting device.

19. A thin-film semiconductor structure comprising:
a substrate;
a continuous thin-film layer on said substrate wherein said thin-film layer comprises one or more thin-film semiconductor structures and one or more thin-film (poly)silane structures and wherein the top surface of said continuous thin-film layer is substantially planar.

20. The thin-film structure according to claim 19 wherein a first semiconductor structure of said one or more thin-film semiconductor structures has a first crystallinity and wherein a second semiconductor structure of said one or more thin-film semiconductor structures has a second crystallinity.

21. A thin-film semiconductor structure comprising:
a substrate;
a continuous thin-film layer on said substrate wherein said thin-film layer comprises one or more thin-film semiconductor structures, and one or more thin-film patterned semiconductor oxide structures wherein said one or more thin-film semiconductor structures are embedded in said one or more thin-film semiconductor oxide structures and wherein the top surface of said continuous thin-film layer is substantially planar.

22. The method according to claim 1 further comprising:
transforming (poly)silane of said layer that is not transformed in a thin-film semiconductor structure into a semiconductor oxide by exposing said (poly)silane to ozone.

23. The method according to claim 1 further comprising:
embedding said thin-film solid-state semiconductor structures in an semiconductor oxide by exposing said (poly)silane comprising said thin-film solid-state semiconductor structures to ozone.

24. The method according to claim 9 wherein the energy density (fluence) of said UV light source is selected such that said transformation of said (poly)silane layer takes place without heating the substrate temperature to temperatures higher than 300° C.

25. The method according to claim 10 wherein transforming one or more parts of said (poly)silane layer comprises:
exposing said one or more parts of said (poly)silane layer to UV light from a (pulsed) laser having energy density (fluence) between 50 and 400 mJ/cm2.

26. The method according to claim 11 wherein transforming one or more parts of said (poly)silane layer comprises:
exposing said one or more parts of (poly)silane layer to light from the light of said a LED array.

27. The method according to claim 12 wherein said (poly)silane layer comprises neopentasilane.
